(19) United States
(12) Patent Application Publication
(10) Pub. No.: US 2019/0018060 A1
(43) Pub. Date: Jan. 17, 2019

(54) Self cleaning Vertical sliding Electrical Contact Device for Semiconductor contacts

(71) Applicant: Jose E. Lopez, Sunnyvale, CA (US)

(72) Inventor: Jose E. Lopez, Sunnyvale, CA (US)

(73) Assignee: Jose E. Lopzed, Sunnyvale, CA (US)

(21) Appl. No.: 16/035,571

(22) Filed: Jul. 13, 2018

Related U.S. Application Data
(60) Provisional application No. 62/533,165, filed on Jul. 17, 2017.

(51) Int. Cl. G01R 31/28; G01R 31/27

(52) U.S. Cl. CPC G01R 31/2863; G01R 31/275; G01R 31/2884

(57) ABSTRACT

The electrical contact device has an insulative, compliant element with a first surface that is next to the load board and has a cavity from the first to the second surface. At the top of the compliant element is an insulative compliant sheet with a hole that aligns with the cavity. At the bottom of the compliant element is an insulative compliant plate with a hole that aligns with the cavity. A first contact element inserts into the compliant plate hole and forming the bottom of the cavity of the compliant element and having a primary protrusion with an oblique surface that faces both the wider cavity opening. A second contact element fits into the hole of the compliant sheet and having a primary protrusion with an oblique surface that mates onto and substantially parallel to the first contact element's oblique surface.

### CROSS REFERENCE TO RELATED APPLICATIONS

The present application claims the benefit of priority to the US provisional patent application of the same title, having application Ser. No. 62/533,165, that was filed on Jul. 17, 2017, which is incorporated herein by reference.

### FIELD

The present invention relates to a test fixture for integrated circuit. The general use is to provide a connection between the leads of a semiconductor device and the conductive terminals of a printed circuit board so as to allow an electrical tester to send electrical signals, measure the electrical response and therefore analyze the internal circuitry of the semiconductor device.

### BACKGROUND OF THE INVENTION

The objective of this invention is to propose a technique of contacting that maintains a reliable electrical contact between the leads of a semiconductor device under test (DUT) to the terminals of a printed circuit board (PCB) or load board so that the resistance is maintained low, prevents debris from entering the internal contact surfaces, minimal upward housing bow and no abrasion of the load board.

Two of the primary techniques for providing semiconductor contacts are utilizing two contact elements biased by an elastomeric element or by spring. In the elastomeric element technique, the contact elements are generally pegs with flanges on the opposite ends inserted in a common cavity of the elastomeric element. An issue arises for those skilled in the arts in that the improper biasing of the contact elements may cause a loss of bias between the contact elements and thereby cause an open contact or high contact resistance in the electrical path through the two contact elements.

Using a spring is another common technique of bias between the two contact elements for those skilled in the arts in the semiconductor testing industry. The contact elements are generally cylindrical bars with end flanges outwardly biased, and a spring between them. The spring and the two contact element's end flanges are generally enclosed within a conductive tube with narrowed ends to contain the end flanges and spring components, and allow the contact elements to slide along the tube. The problem is usually the electrical contact between the contact element that contacts the leads of the semiconductor device under test and the proximate narrowed end of the tube. After multiple actuations of this contact element, the clearance between the contact element and the narrowed end of the tube increases due to wear and the resulting gap reduces the contact reliability, along with debris entering, causing unstable resistance, opens and even jams for those skilled in the arts.

Still another technique for contacting used for those skilled in the arts within the semiconductor testing industry is a contact element is suspended between two elastomeric elements. The rolling of the contact element onto the load board minimizes contact pad wear but any slight slippage on the load board pad surface could still create wear due to the contact element's abrasion to the load board. Yet another concern would be debris entering in-between the contact element and the load board and embed itself due to the rolling action of the contact element. An additional concern would be the upward bulge of the two elastomeric elements during device actuation causing upward housing bow and compromising the contact element's bias to the load board.

### SUMMARY OF THE INVENTION

The invention consists of a generally electrically insulative, compliant element with a first surface that is usually proximate with the surface of a load board. The compliant element has a second surface that is generally parallel and spaced from the compliant element's first surface and is usually proximate the device leads. The compliant element has a generally conical cavity from the first surface to the second surface, which is the end with the wider opening. At the top of this compliant element is a generally electrically insulative, similarly or more compliant sheet with a hole that generally aligns with the narrower conical cavity opening at the first surface. At the bottom of this compliant element is a generally electrically insulative, vertically compliant plate that is more rigid than the compliant element with a hole that generally aligns with the bottom opening of the conical cavity at the first surface.

A first contact element made of conductive material that inserts into the compliant plate hole and conical cavity forming the bottom of said cavity. The first contact element having a primary protrusion with an oblique surface that faces both the wider conical cavity opening and the compliant wall of the conical cavity. Additionally, the first contact element has a hump at the opposing surface from the oblique surface that engages or closely engages the proximate wall of the conical cavity. Furthermore, the first contact element has at least two divots proximate the first surface that interferes with the compliant plate so as to serve as a retention feature for the first contact element.

There is a second contact element made of conductive material that fits into the hole of the compliant sheet and proximate the wider end of the conical cavity. The second contact element having a primary protrusion with an oblique surface that generally mates onto and substantially parallel to the first contact element's oblique surface. Additionally, the second contact element has a hump at the opposing surface from the oblique surface that engages or closely engages the proximate wall of the conical cavity. Furthermore, the second contact element has two secondary protrusions above the compliant sheet, at the end that engages the device leads and both extend laterally to an imaginary line crossing the general direction of the second contact element's primary protrusion.

The second contact element has an external contact surface facing away from the first contact element's contact surface. When the first contact element is engaged with a generally firm immovable surface, the second contact element responds to an inward vector applied to its contact surface by slippage along both contact elements' oblique surfaces to deflect the compliant sheet and conical cavity wall while the force is present. When this inward force is removed the return of the compliant sheet and conical cavity back to its original shape urges the second contact element back to its approximate initial position.

An important feature is the position of both contact elements' primary protrusions so that their oblique contact surfaces are covered from debris.

### BRIEF DESCRIPTION OF THE DRAWINGS

The drawings illustrate the design and utility of embodiments, in which similar elements are referred to by common reference numerals. These drawings are not necessarily drawn to scale. In order to better appreciate how the above recited and other advantages and objects are obtained, a more particular description of the embodiments will be rendered, which are illustrated in the accompanying drawings. These drawings depict only typical embodiments and are not therefore to be considered limiting of its scope.

FIG. 1 illustrates a half-section view embodiment of the invention with two contact elements within the three compliant elements.

FIG. 2 illustrates a half-sectioned assembly consisting of the compliant sheet, compliant element and compliant plate.

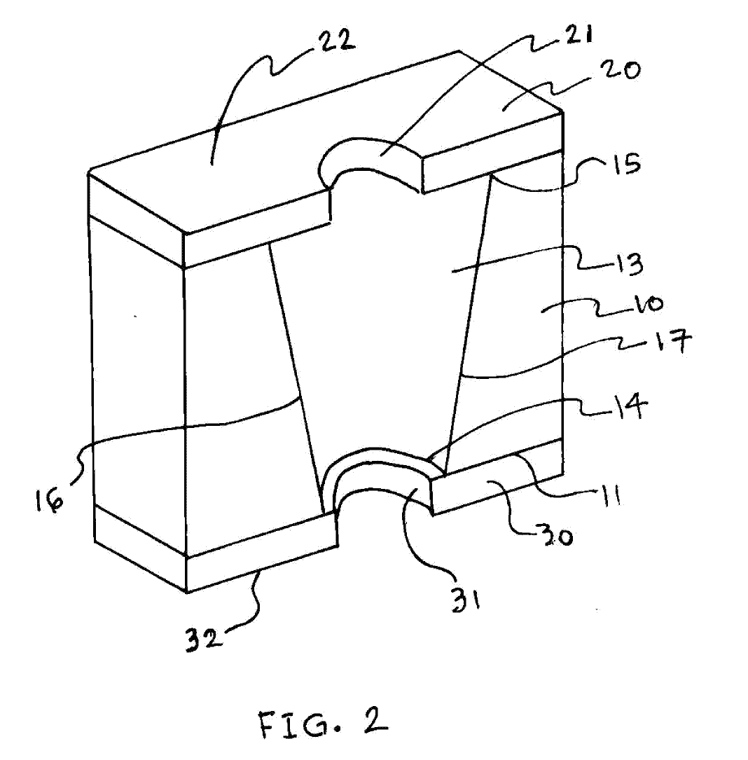

FIG. 3 illustrates the first contact element.

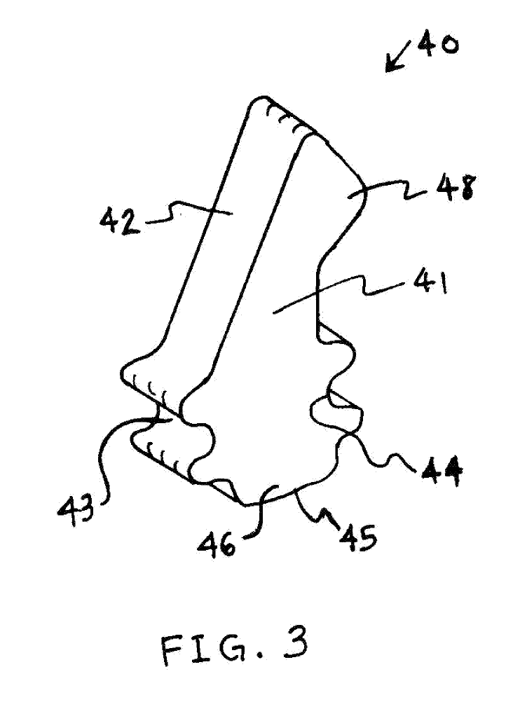

FIG. 4 illustrates the second contact element.

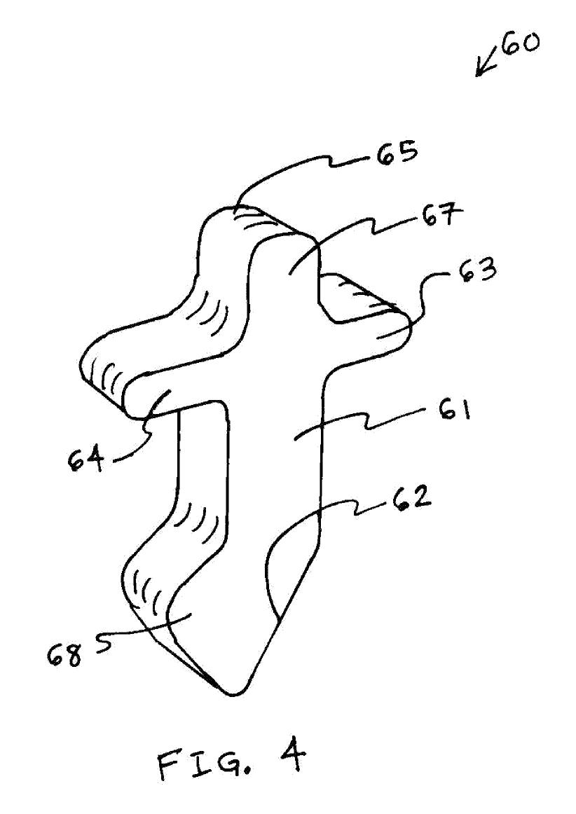

### DETAILED DESCRIPTION

Various embodiments are described hereinafter with reference to the figures. The figures are not drawn to scale and those elements of similar structures or functions are represented by like reference numerals throughout the figures. It should also be noted that the figures are only intended to facilitate the description of the embodiments. They are not intended as an exhaustive description of the invention or as a limitation on the scope of the invention. In addition, an illustrated embodiment does not need to have all the aspects or advantages shown. An aspect or an advantage described in conjunction with a particular embodiment is not necessarily limited to that embodiment and can be practiced in any other embodiments even if not so illustrated.

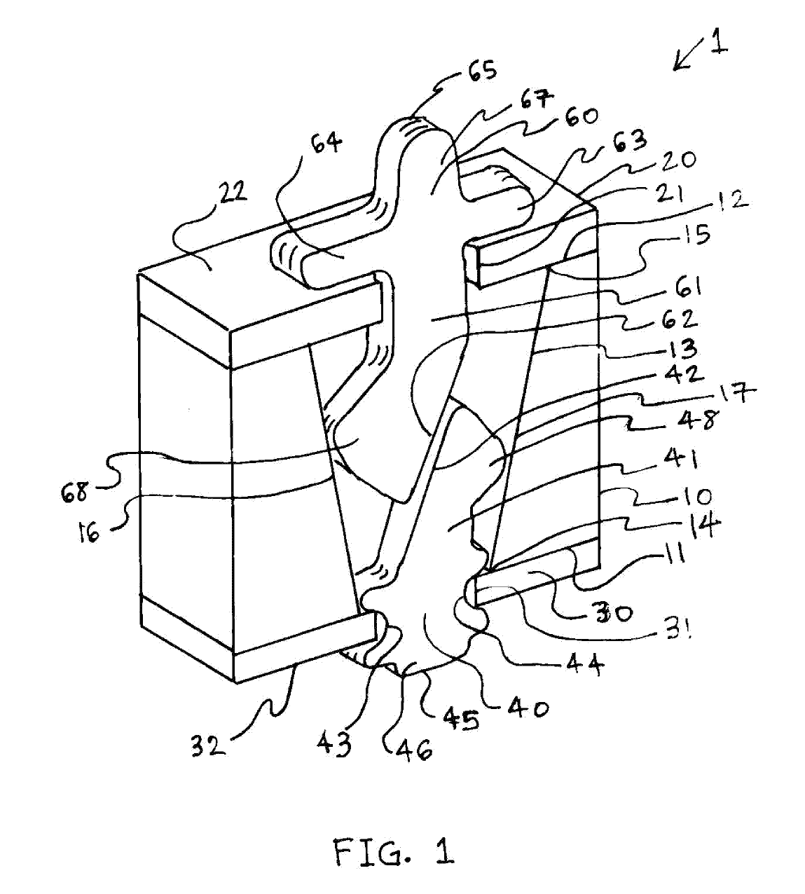

FIG. 1 illustrates a cross sectioned view of the preferred embodiment of an electrical contact device 1, the removed part of the section is symmetrical to what is shown. FIG. 1 is an electrical connector 1 consisting of an electrically insulative, resilient compliant element 10 usually made of relatively insulative solid rubber or foam rubber or an equivalent material, which is typically positioned between the device under test (DUT) and the circuit terminals, with a conical cavity 13 that extends through the thickness thereof from the first opposed surface 11 to the second opposed surface 12 of the elastomeric element 10, at the proximity of the circuit terminals and device lead respectively. The diameter of the top of conical cavity is significantly larger than the diameter at the bottom of the cavity. The diameter ratio at the top of the cavity is two to three times the diameter at the bottom of the conical cavity. The conical cavity 13 maybe manufactured by a laser wherein the cutting beam is focused to fan out creating the conical shaped hole desired.

At the top of this compliant element 10 is an insulative, similarly or more compliant—compliant sheet 20, that could be made of rubber, with a hole 21 that generally aligns with the narrower conical cavity opening 14 at the first surface 11. The compliant sheet 20 can be glued to the compliant element 10 or it can be part of a usually rubber mold or combined molds or pours which are composed of the combined shapes of both the compliant sheet 20 and the compliant element 10.

At the bottom of this compliant element 10 is an insulative, vertically compliant plate 30, that could be made of Kapton, with a hole 31 that generally aligns the narrower opening of the conical cavity 14. The compliant plate 30 is generally more rigid than the compliant element 10 so as to guide the horizontal spacing of the compliant element's conical cavity 13 and first contact element 40 which in turn guides the horizontal location of the second contact element 60. This is critical in an application where multiple pairs of first and second contact elements 40; 60 are guided into a matching plurality of generally aligned holes 21, 13 and 31 within the corresponding compliant sheet 20, compliant element 10 and compliant plate 30 layers.

In addition, there is a first contact element 40, generally made of copper or other conductive material that can be machined to the shape illustrated from a flat plate, with a primary protrusion 41 that vertically fits into the conical cavity 13 and fits into the narrower hole end 14 of the cavity 13 proximate the first surface 11 of the elastomeric element 10. The first contact element 40 has an oblique surface 42 that faces both the wider hole 15 opening of the conical cavity 13 and the wall 16 of the conical cavity 13. Additionally, the first contact element 40 has a hump 48, at the opposing surface from the oblique surface 42, which engages or closely engages the wall 17 of the conical cavity. Furthermore, the first contact element 40 has at least two divots 43, 44 near the bottom of the first contact element, that engages the edges of the hole of the bottom compliant plate 30 so as to serve as a retention feature for the first contact element 40. The divots 43, 44 near the bottom of the first contact element 40 fit vertically into the compliant plate 30 to minimize the movement of the first contact element. The bottom portion 45 of the first contact element 40 makes an electrical contact PCB or the load board (not shown).

Furthermore, there is a second contact element 60, generally made of copper or other conductive material machined to the shape illustrated from a flat plate, with a primary protrusion 61 that fits into the hole 21 of the top compliant sheet 20; proximate the second surface 12 of the compliant element 10. The second contact element 60 having an oblique surface 62 that mates onto and substantially parallel to the first contact element's oblique surface 42. Furthermore, the second contact element 60 has secondary protrusions 63, 64 above the compliant sheet 20 proximate to the contact surface 65 that engages the device leads and extends laterally from an imaginary line generally crossing the general direction of the second contact element's 60 primary protrusion 61. The second contact element 60 has a contact surface 65 facing away from the first contact element's contact surface 45. The two secondary protrusions 63, 64 have the benefit of covering the opening at the hole 21 of the compliant sheet 20 on the side where debris may enter and possibly contaminate the oblique contact surfaces 42, 62. The two secondary protrusions 63, 64 do not have to be of the same length and one maybe eliminated to allow for space between multiple second contact elements 60 above the compliant sheet 20, in the case where multiple first and second contact element pairs 40, 60 are installed within the compliant sheet 20, compliant element 10 and compliant plate 30 assembly layers.

The second contact element 60 has a nub 67 that provides an electrical contact surface 65 with the device lead (not shown) and extends outward from the top surface 22 of the compliant sheet 20 and typically within the general direction of the primary protrusion 61. The first contact element has a nub 46 that provides an electrical contact surface 45 with the load board (not shown) and extends outward from the bottom surface 32 of the compliant plate 30 and typically within the general direction of the primary protrusion 41. The contact surfaces of 65, 45 of the second contact element 60 and first contact element respectively may have a variety of shapes such as being rounded, multi-humped, spiked, angled, V-cut depending on the contact dynamics desired for the external contact surface it is contacting.

Both the first 40 and second 60 contact element's primary protrusion 41, 61 usually extends more than halfway through the length of the conical cavity 13 so that their oblique surfaces 42, 62 engage.

The second contact element 60 has an external contact surface 65 facing away from the first contact element's 10 contact surface 45. With the first contact element's 40 contact surface 45 engaged with a generally firm immovable surface (not shown), such as the terminals of a circuit board, the second contact element 60 responds to an inward force applied to its contact surface 65 by slippage along both contact element's 40, 60 oblique surfaces 42, 62 respectively. In addition, both second contact element's 60 secondary protrusions 63, 64 engage with the proximate compliant sheet's top surface 22 when an inward force is applied upon the contact surface 65. Generally, the more inward force applied the further the top surface 22 is deflected. An increase in the compliant sheet's 20 durometer or rigidity would cause an increase in the force per translation distance required to actuate the second contact element 60 inward in a generally directly proportional relationship.

The conical cavity 13 provides deflection and expansion space for the deflection of the compliant sheet 20 so as to prevent excessive forces and prolong the life of the compliant sheet 20. In addition, while the inward force is applied, the second contact element's 60 hump 68 engages and deflects the proximate wall 16 of the conical cavity 13 and the first contact element's 40 hump 48 engages and deflects the proximate wall 17 of the conical cavity 13, thereby ensuring the oblique surfaces 62, 42 engage and make physical contact ensuring electrical between the load board and the device lead. The oblique surfaces of the first contact element and the second contact element ensure that the contact surfaces are clean. The two humps' 68, 48 engaging with their respective walls 16, 17 also aligns the second contact element 60 with the first contact element 40 along the general direction of the primary protrusion 41.

When this inward force is removed, the return of the compliant sheet 20 and conical cavity 13 back to their original shapes causes the second contact element 60 back to its approximate initial position.

In an alternate configuration of the contact elements 40, 60, it is possible for the nubs 46, 67 to be eliminated and utilize the surfaces that are generally flushed with the two divots 43, 44 of the first contact element 40 and the secondary protrusions 63, 64 of the second contact element 60 as electrical contact surfaces.

Still in another alternate configuration, the conical cavity may not be shaped as a cone it could also be shaped in other ways such as cylindrical, rectangular, square or elliptical cross-sectioned such that expansion space for the compliant sheet's 20 deflection is still provided and the first and second contact element's hump 48, 68, to wall 17, 16 close engagement are still present.

All examples and conditional language recited herein are intended for educational purposes to aid the reader in understanding the principles of the invention and the concepts contributed by the inventor to furthering the art, and are to be construed as being without limitation to such specifically recited examples and conditions. Moreover, all statements herein reciting principles, aspects, and embodiments of the invention, as well as specific examples thereof, are intended to encompass both structural and functional equivalents hereof. Additionally, it is intended that such equivalents include both currently known equivalents as well as equivalents developed in the future, i.e., any elements developed that perform the same function, regardless of structure.

The invention claimed is:

1. An electrical contact device comprising of:
a resilient electrically insulative compliant element with a vertical cavity;
a resilient electrically insulative compliant sheet with a hole that aligns with said cavity of said compliant element;
a resilient electrically insulative compliant plate with a hole that aligns with said cavity opening of said compliant element and is placed on bottom of said compliant element;
a first contact element made of conductive material that fits into said vertical cavity forming the bottom of said cavity; and
said first contact element having a primary protrusion with an oblique surface; and
said first contact element has at least two divots that engages the edges of the hole of said compliant plate;
a second contact element made of conductive material that fits into the hole of said compliant sheet;
said second contact element having a primary protrusion with an oblique surface; and
said second contact element has two secondary protrusions above said compliant sheet that extends laterally crossing the direction of said first contact element's primary protrusion.

2. The contact device of claim 1, wherein said cavity of the compliant element is cylindrical wherein the top portion of the cavity is wider than bottom.

3. The contact device of claim 2, wherein said first contact element's primary protrusion having said oblique surface which mates onto and substantially parallel to said second contact element's oblique surface.

4. The contact device of claim 3 further comprising of:
opposing sides of the oblique surfaces for said first contact element having a hump that contacts or almost impinges said walls of said cavity of contact element; and
opposing sides of the oblique surfaces for said second contact element having a hump that contacts or almost impinges said walls of said cavity of contact element;

5. The contact device of claim 4, wherein said hole in the complete sheet is smaller than the diameter of said cavity of said compliant element.

6. The contact device of claim 5, wherein said hole in said compliant plate is smaller in diameter of said cavity of said compliant element.

7. The contact device of claim 6, wherein the cavity of the compliant element can be of other shapes such as cylindrical, rectangular, square or elliptical cross-sectioned.

8. The contact device of claim 6, wherein the first conductive contact element's base has at least one nub that extend outward and generally engages the traces of a load board.

9. The contact device of claim 6, wherein the first contact element is made of copper.

10. The contact device of claim 6, wherein the second contact element is made of copper.

11. The contact device of claim 6, wherein the second conductive element's member has at least one nub that extend outward and generally engages the device leads.

12. The contact device of claim 6, wherein the second conductive element's secondary protrusions are of different lengths.

13. The contact device of claim 6, wherein the compliant sheet and the compliant element are combined as one component.

14. The contact device of claim 6, wherein the first conductive element is longer than the second conductive element.
